(19) United States
(12) Patent Application Publication
(10) Pub. No.: US 2025/0204110 A1
(43) Pub. Date: Jun. 19, 2025

(54) LIGHT EMITTING STRUCTURE FOR VEHICLE WINDOW

(71) Applicant: GM Global Technology Operations LLC, Detroit, MI (US)

(72) Inventors: Jonglee Park, Novi, MI (US); Julien P. Mourou, Bloomfield Hills, MI (US); Michael K. Larsen, Warren, MI (US)

(21) Appl. No.: 18/543,360

(22) Filed: Dec. 18, 2023

(51) Int. Cl. H01L 33/60; B60Q 3/208; B60Q 3/60; G02B 27/30; H01L 33/38

(52) U.S. Cl. CPC H10H 20/856; B60Q 3/208; B60Q 3/60; G02B 27/30; H10H 20/8316

(57) ABSTRACT

A vehicle window of a vehicle includes a light emitting assembly having a light emitting element package configured to emit light from a light emitting surface, and a reflector having a reflection surface that faces the light emitting surface and that is configured to reflect light from the light emitting element package.

### INTRODUCTION

The subject disclosure relates to vehicles, and in particular to a light emitting structure for a vehicle window.

### SUMMARY

In one exemplary embodiment, a light emitting assembly configured to be disposed within a vehicle window of a vehicle includes a light emitting element package configured to emit light from a light emitting surface, and a reflector having a reflection surface that faces the light emitting surface and that is configured to reflect light from the light emitting element package.

In addition to one or more of the features described herein, the vehicle defines a longitudinal axis, the light emitting assembly forms a first angle θ with the longitudinal axis, and the reflection surface is configured to reflect at least some light from the light emitting element package in a direction along the longitudinal axis.

In addition to one or more of the features described herein, the light emitting assembly further includes a base board on which the reflector is disposed, wherein the reflection surface forms a second angle α with the base board, and wherein the reflector is structured such that the second angle α satisfies an equation α=90°−θ/2.

In addition to one or more of the features described herein, the light emitting assembly further includes an electrode electrically connected to the light emitting element package and configured to supply power to the light emitting element package, wherein the reflector is disposed on the electrode.

In addition to one or more of the features described herein, the light emitting assembly further includes a first electrode extending in a first direction, and a second electrode extending in a second direction different from the first direction, wherein the reflector is disposed on the first electrode or the second electrode.

In addition to one or more of the features described herein, the light emitting assembly further includes a collimator disposed between the light emitting element package and the reflection surface of the reflector configured to converge light emitted by the light emitting element package towards the reflection surface.

In addition to one or more of the features described herein, the light emitting element package is disposed on an integrated circuit.

In addition to one or more of the features described herein, the light emitting assembly further includes an electrode on which the reflector is disposed, an insulation layer on which the light emitting element package and the electrode are disposed, and a connector disposed in the insulation layer connecting the light emitting element package and the electrode.

In addition to one or more of the features described herein, the light emitting assembly further includes a base board having a mounting surface on which the light emitting element package is disposed, wherein the reflector is a reflective layer disposed on a mounting surface of the base board.

In another exemplary embodiment, a vehicle window of a vehicle includes a light emitting assembly including a light emitting element package configured to emit light from a light emitting surface, and a reflector having a reflection surface that faces the light emitting surface and that is configured to reflect light from the light emitting element package.

In addition to one or more of the features described herein, the vehicle defines a longitudinal axis, the light emitting assembly forms a first angle θ with the longitudinal axis, and the reflection surface is configured to reflect at least some light from the light emitting element package in a direction along the longitudinal axis.

In addition to one or more of the features described herein, the vehicle window further includes a base board on which the reflector is disposed, wherein the reflection surface forms a second angle α with the base board, and wherein the reflector is structured such that the second angle α satisfies an equation α=90°−θ/2.

In addition to one or more of the features described herein, the vehicle window further includes an electrode electrically connected to the light emitting element package and configured to supply power to the light emitting element package, wherein the reflector is disposed on the electrode.

In addition to one or more of the features described herein, the vehicle window further includes a first electrode extending in a first direction, and a second electrode extending in a second direction different from the first direction, wherein the reflector is disposed on the first electrode or the second electrode.

In addition to one or more of the features described herein, the vehicle window further includes a collimator disposed between the light emitting element package and the reflection surface of the reflector configured to converge light emitted by the light emitting element package towards the reflection surface.

In addition to one or more of the features described herein, the light emitting element package is disposed on an integrated circuit.

In addition to one or more of the features described herein, the vehicle window further includes an electrode on which the reflector is disposed, an insulation layer on which the light emitting element package and the electrode are disposed, and a connector disposed in the insulation layer connecting the light emitting element package and the electrode.

In addition to one or more of the features described herein, the vehicle window further includes a base board having a mounting surface on which the light emitting element package is disposed, wherein the reflector is a reflective layer disposed on a mounting surface of the base board.

In addition to one or more of the features described herein, the light emitting element package and the reflector are disposed between a first glass layer and a second glass layer.

In yet another exemplary embodiment, a vehicle defining a longitudinal axis and a forward direction and a rear direction along the longitudinal axis includes a vehicle window including a light emitting assembly, the light emitting assembly including a light emitting element package configured to emit light from a light emitting surface, an electrode electrically connected to the light emitting element package and configured to supply power to the light emitting element package, a reflector disposed on the electrode and having a reflection surface that faces the light emitting surface and that is configured to reflect light from the light emitting element package, and a base board on which the reflector is disposed, wherein the light emitting assembly forms a first angle θ with the longitudinal axis, wherein the reflection surface is configured to reflect at least some light from the light emitting element package in a direction along the longitudinal axis, wherein the reflection surface forms a second angle α with the base board, and wherein the reflector is structured such that the second angle α satisfies an equation α=90°−θ/2.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a side perspective view of a vehicle having a first light emitting structure according to one or more embodiments;

FIG. 2 is a rear perspective view of a vehicle having a second light emitting structure according to one or more embodiments;

FIG. 3 is a side view of a front windshield having a first light emitting structure according to one or more embodiments;

FIG. 4. is a side view of a rear window having a second light emitting structure according to one or more embodiments;

FIG. 5 is a schematic orthogonal view of a light emitting assembly according to one or more embodiments;

FIG. 6 is a schematic side cross-sectional view of the light emitting assembly taken at 6-6 in FIG. 5;

FIG. 7 is a schematic side cross-sectional view of a light emitting assembly according to one or more embodiments;

FIG. 8 is a schematic orthogonal view of a light emitting assembly according to one or more embodiments;

FIG. 8A shows a schematic cross-sectional view of the light emitting assembly taken at 8A-8A in FIG. 8;

FIG. 8B shows a schematic cross-sectional view of the light emitting assembly taken at 8B-8B in FIG. 8;

FIG. 9 is a schematic orthogonal view of a light emitting assembly according to one or more embodiments;

FIG. 10 is a schematic side cross-sectional view of a light emitting assembly according to one or more embodiments;

FIG. 11 is a schematic side cross-sectional view of a light emitting assembly according to one or more embodiments;

FIG. 12 is a schematic side cross-sectional view of a light emitting assembly according to one or more embodiments;

FIG. 13 is a schematic side cross-sectional view of a light emitting assembly according to one or more embodiments;

FIG. 14 is a schematic side cross-sectional view of a light emitting assembly according to one or more embodiments;

FIG. 15 shows a schematic orthogonal view of a light emitting assembly according to one or more embodiments; and

FIG. 15A shows a schematic cross-sectional view of the light emitting assembly taken at 15A-15A.

### DETAILED DESCRIPTION

The following description is merely exemplary in nature and is not intended to limit the present disclosure, its application or uses. It should be understood that throughout the drawings, corresponding reference numerals indicate like or corresponding parts and features.

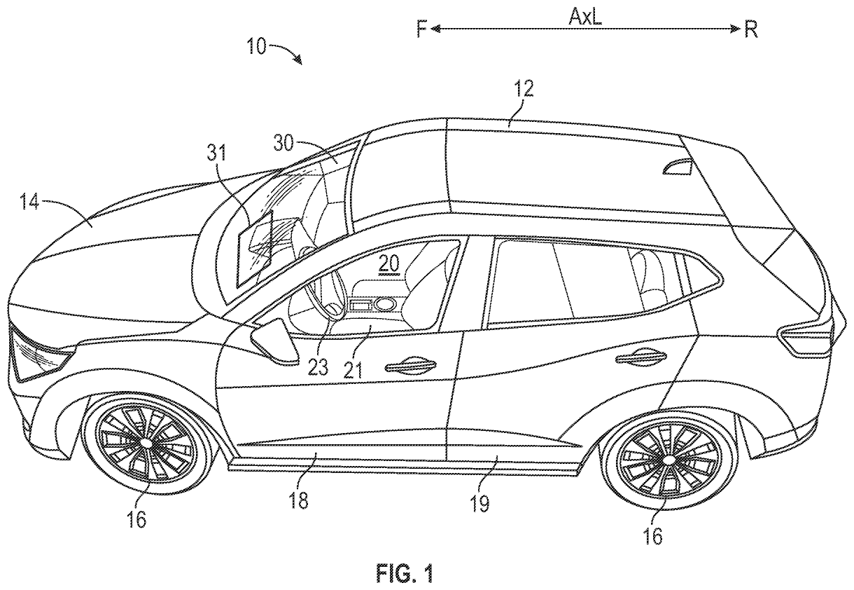

FIG. 1 shows a vehicle 10 according to a non-limiting example. The vehicle 10 extends in along a longitudinal axis AxL and defines a forward direction F and a rearward direction R along the longitudinal axis AxL. The vehicle 10 includes a vehicle body 12 supported on a plurality of wheels 16. The vehicle body 12 defines, in part, a passenger compartment 20 in which a driver seat 21 and a steering wheel 23 may be disposed. One or more of the plurality of wheels 16 may be steerable via the steering wheel 23. The vehicle body 12 further defines, in part, a prime mover compartment 14 that houses a prime mover. The prime mover may be, for example, an engine, a motor, or both an engine and a motor in a hybrid configuration. The vehicle body 12 may further include a front door 18 and a rear door 19. A front windshield 30 is disposed in front of the passenger compartment 20. The front windshield 30 may include a first light emitting structure 31. For example, the first light emitting structure 31 may be, for example, a heads-up display (HUD) that irradiates towards the passenger compartment 20 or may be other types of lighting that irradiates towards the passenger compartment 20. Alternatively, the first light emitting structure 31 may be a type of lighting that irradiates away from the passenger compartment 20. The front windshield 30 may be an example of a vehicle window.

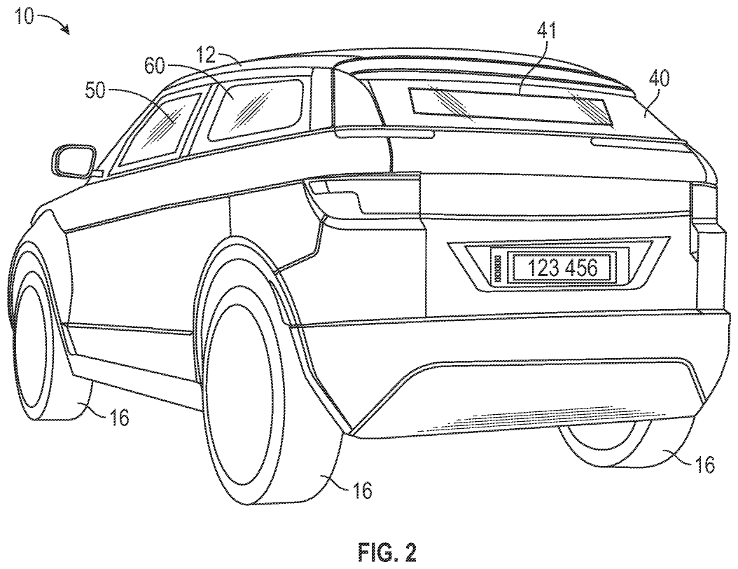

FIG. 2 shows a rear perspective view of a vehicle 10 according to a non-limiting example. As shown in FIG. 2, the vehicle 10 may further include a rear window 40, a pair of front side windows 50 and a pair of rear side windows 60. The rear window 40 may include a second light emitting structure 41. The second light emitting structure 41 may be, for example, functional lighting, an informational display, or an ornamental display. The second light emitting structure 41 may function as, for example, a tail light, a brake light, a turn signal, or other rear-irradiating types of lights for the vehicle 10. The rear window 40 may be an example of a vehicle window.

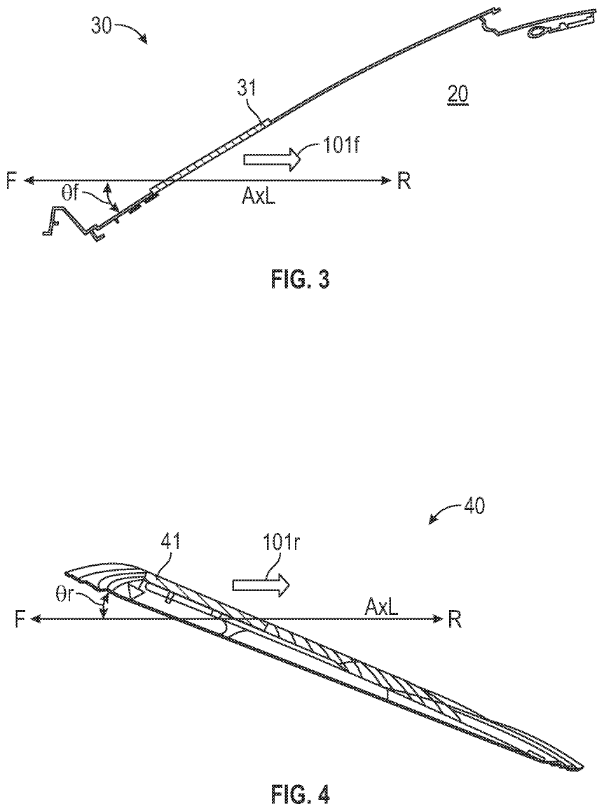

FIG. 3 shows a side sectional view of a front windshield 30 having a first light emitting structure 31 according to one or more embodiments. The first light emitting structure 31 forms an angle θf with the longitudinal axis AxL of the vehicle 10. At least portions of the first light emitting structure 31 may be curved such that the angle θf may differ depending on a position within the first light emitting structure 31. The first light emitting structure 31 may be structured to emit light 101f in a rearward direction R of the vehicle 10 towards the passenger compartment 20. The angle θf may be an example of a first angle θ.

FIG. 4 shows a side sectional view of a rear window 40 having a second light emitting structure 41 according to one or more embodiments. The second light emitting structure 41 forms an angle θr with the longitudinal axis AxL of the vehicle 10. At least portions of the second light emitting structure 41 may be curved such that the angle θr may differ depending on a position within the second light emitting structure 41. The second light emitting structure 41 may be structured to emit rearward light 101r in a rearward direction R of the vehicle 10. The angle θr may be an example of a first angle θ.

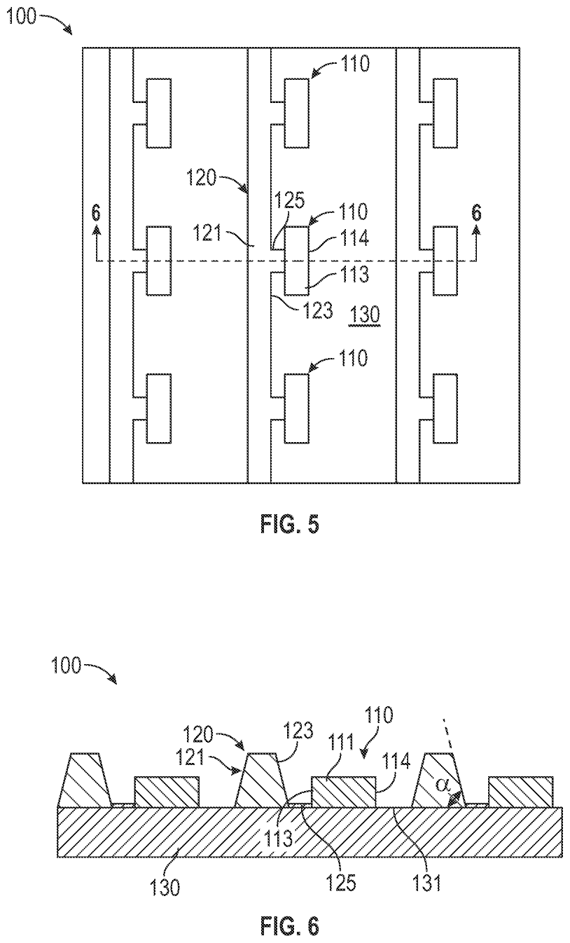

FIG. 5 shows a schematic orthogonal view of a light emitting assembly 100 according to one or more embodiments. The light emitting assembly 100 may be part of the first light emitting structure 31 or the second light emitting structure 41. As part of the first light emitting structure 31, the light emitting assembly 100 may face a rear direction R of the vehicle 10 (see FIGS. 1 and 3). As part of the second light emitting structure 41, the light emitting assembly 100 may face a rear direction R of the vehicle (see FIGS. 2 and 4). FIG. 6 shows a cross-sectional view of the light emitting element taken at 6-6 in FIG. 5. The light emitting assembly 100 includes base board 130 on which light emitting element packages 110 and electrodes 120 are mounted. A connector 125 may electrically connect the light emitting element package 110 to the electrode 120. The electrodes 120 may supply power to the light emitting element packages 110. The base board 130 may be, for example, a thin film transistor backplane. The thin film transistor backplane may be installed on an underlying substrate.

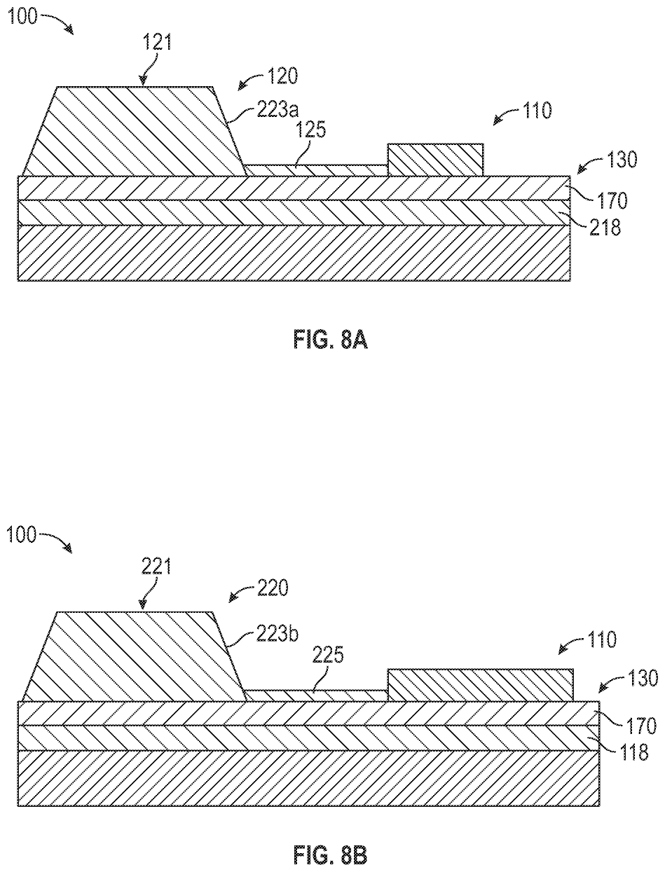

As shown in FIG. 5, one or more of the electrode 120 may electrically connect multiple light emitting element packages 110. The light emitting element package 110 may include one or more light emitting elements 119 (see FIG. 8). The light emitting element(s) 119 may be, for example, micro-light emitting diode(s) (i.e., micro-LED(s)). The light emitting element package 110 may be a formed of a single light emitting element 119. Each of the light emitting element packages 110 may include a main body 111 having a first light emitting surface 113 and a second light emitting surface 114. While FIG. 6 shows the light emitting element package 110 with a first light emitting surface 113 and a second light emitting surface 114, according to one or more embodiments, the light emitting element package 110 may only have the first light emitting surface 113. According to one or more embodiments, the light emitting elements 119 may be disposed on top of the light emitting element package 110.

The electrode 120 may include a reflector 121 at least in a portion that faces a light emitting element package 110. That is, the reflector 121 may be formed on or coated on at least a portion of the electrode 120 that faces a light emitting element package 110. Alternatively, the reflector 121 may be formed along an entire length of the electrode 120. As a non-limiting example, the reflector 121 may be formed by depositing a metal layer on the electrode 120 or by removing a layer of metal from the electrode 120.

The reflector 121 of the electrode 120 may include a reflection surface 123 facing the first light emitting surface 113 of the light emitting element package 110 to which the electrode 120 is connected via the connector 125. The second light emitting surface 114 of the light emitting element package 110 faces away from the reflection surface 123.

As shown in FIG. 6, the base board 130 may include a mounting surface 131 on which the light emitting element package 110 and the electrode 120 are mounted. The connector 125 may be mounted on or be formed within the base board 130. The light emitting element package 110, the electrode 120, and/or the connector 125 may be directly or indirectly mounted on the mounting surface 131 of the base board 130. The reflection surface 123 may be inclined with respect to the mounting surface 131 of the base board 130 so as to form an acute angle α with the mounting surface 131. The acute angle α may be an example of a second angle.

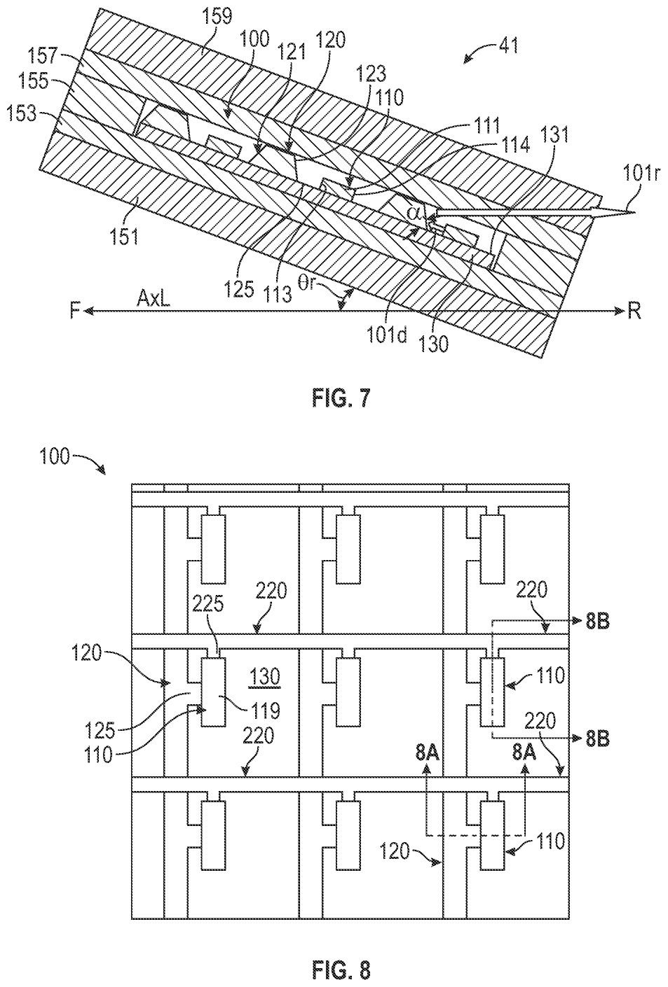

FIG. 7 shows a schematic cross-sectional view of a second light emitting structure 41 including a light emitting assembly 100 according to one or more embodiments. While the light emitting assembly 100 shown in FIG. 7 is configured to be part of a second light emitting structure 41 of a rear window 40 (see FIGS. 2 and 4), such a structure may be disposed on a first light emitting structure 31 of a front windshield 30 (see FIGS. 1 and 3) by rotating (i.e., flipping) the light emitting assembly 100. The light emitting assembly 100 may be disposed between a first glass layer 151 and a second glass layer 159. The light emitting assembly 100 may further be embedded between one or more support layers 153, 155, 157 that provide stiffness to prevent excessive deformation that may damage components of the light emitting assembly 100.

As shown in FIG. 7, the second light emitting structure 41 forms an angle θr with the longitudinal axis AxL, and the reflection surface 123 of the reflector 121 forms an acute angle α with the mounting surface 131 of the base board 130. According to one or more embodiments, the reflector 121 may be structured such that the acute angle α satisfies the equation α=90°−θr/2. If the light emitting assembly 100 is part of a first light emitting structure 31 of a front windshield 30 (see FIGS. 1 and 3), according to one or more embodiments, the reflector 121 may be structured such that the acute angle α satisfies the equation α=90°−θf/2. Light 101d emitted from the first light emitting surface 113 of the light emitting element package 110 may be reflected by the reflection surface 123 towards a rearward direction R such that the light emitting assembly 100 may emit rearward light 101r.

FIG. 8 shows a schematic orthogonal view of a light emitting assembly 100 according to one or more embodiments. The light emitting assembly 100 in FIG. 8 includes a base board 130 on which a light emitting element package 110 with a plurality of light emitting elements 119 and electrodes 120 may be disposed similarly to one or more of the above embodiments. The light emitting assembly 100 may further include additional electrodes 220. The additional electrodes 220 may extend in a direction different from the electrodes 120. The additional electrodes 220 may extend orthogonally to the electrodes 120. A connector 125 may extend between the light emitting element package 110 and the electrode 120, and an additional connector 225 may extend between the light emitting element package 110 and the additional electrode 220.

FIG. 8A shows a schematic cross-sectional view of the light emitting assembly 100 taken at 8A-8A in FIG. 8, and FIG. 8B shows a schematic cross-sectional view of the light emitting assembly 100 taken at 8B-8B in FIG. 8. The electrodes 120 may include reflectors 121 as shown in FIG. 8A, and/or the additional electrodes 220 may include reflectors 221 as shown in FIG. 8B. The electrodes 120 may include reflectors 223a at a portion facing the light emitting element package 110. The additional electrodes 220 may include reflectors 223b at a portion facing the light emitting element package 110. According to one or more embodiments, the reflectors 221 may be formed on the additional electrodes 220 but not the electrodes 120. The electrodes 120 may be an example of first electrodes that extend in a first direction, the reflector 121 may be an example of first reflectors. The additional electrodes 220 may be an example of second electrodes that extend in a second direction. The reflectors 221 may be an example of second reflectors.

The base board 130 may include an insulation layer 170 and a second electrode layer 218 for connection to the electrode 120 under the insulation layer 170 for the portion of the light emitting assembly 100 shown in FIG. 8A. The base board 130 may include the insulation layer 170 and a first electrode layer 118 for connection to the additional electrode 220 under the insulation layer 170 for the portion of the light emitting assembly 100 shown in FIG. 8B.

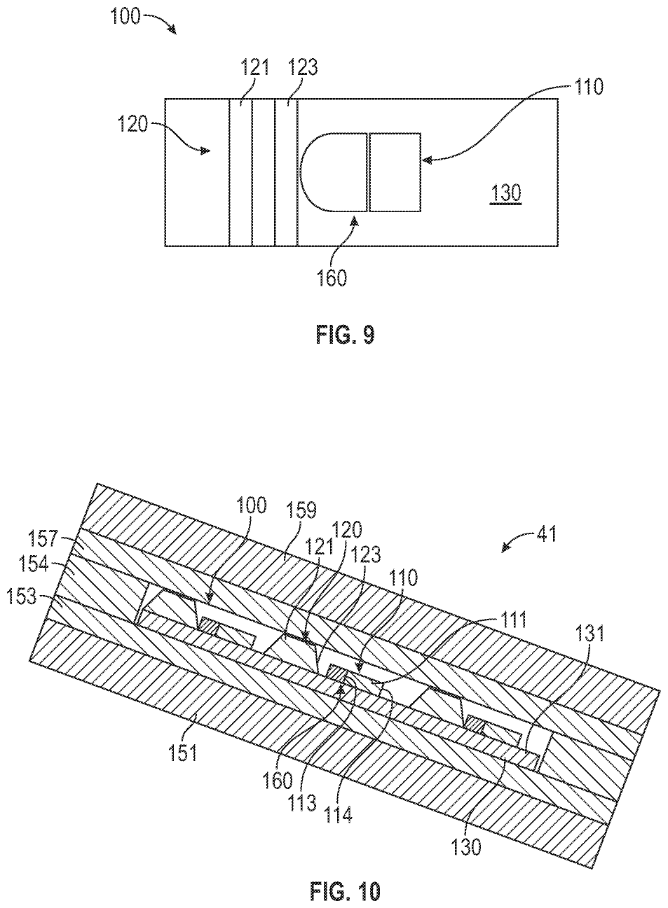

FIGS. 9 and 10 show schematic orthogonal and side cross-sectional views of a light emitting assembly 100 according to one or more embodiments. While the light emitting assembly 100 shown in FIGS. 9 and 10 is configured to be part of a second light emitting structure 41 of a rear window 40 (see FIGS. 2 and 4), such a structure may be disposed on a first light emitting structure 31 of a front windshield 30 (see FIGS. 1 and 3) by rotating (i.e., flipping) the light emitting assembly 100. As shown in FIGS. 9 and 10, the light emitting assembly 100 may include collimators 160 optically coupled to the light emitting element packages 110. The collimator 160 may be structured to converge light emitted by the light emitting element package 110 to which it is coupled and emit the converged light to the reflector 121. Thus, the collimator 160 may improve optical efficiency of the light emitting element packages 110.

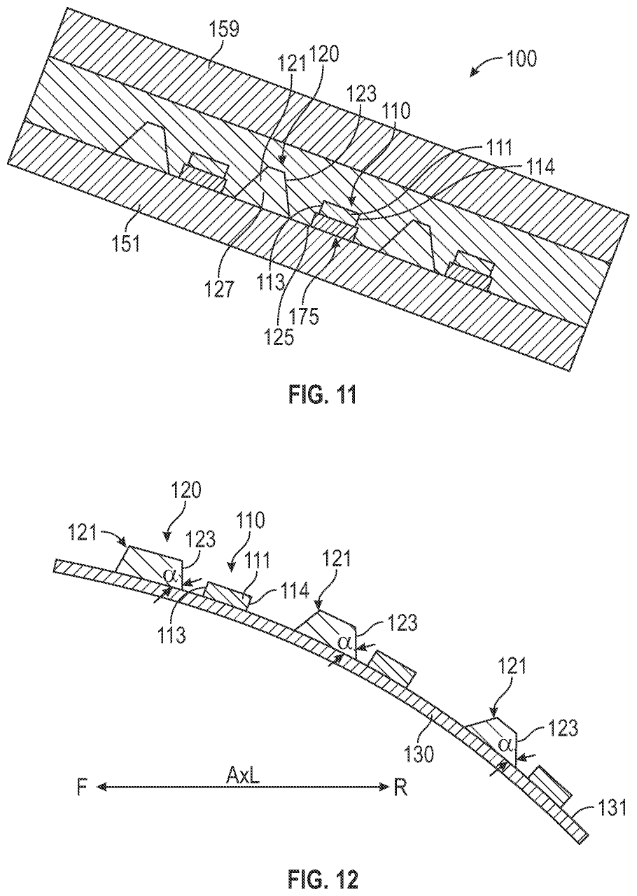

FIG. 11 shows a schematic cross-sectional view of a light emitting assembly 100 according to one or more embodiments. While the light emitting assembly 100 shown in FIG. 11 is configured to be part of a second light emitting structure 41 of a rear window 40 (see FIGS. 2 and 4), such a structure may be disposed on a first light emitting structure 31 of a front windshield 30 (see FIGS. 1 and 3) by rotating (i.e., flipping) the light emitting assembly 100. As shown in FIG. 11, the light emitting assembly 100 may include an integrated circuit 175 integrated into the light emitting element package 110. The integrated circuit 175 may replace the base board 130. While in one or more of the above embodiments, a thin film transistor backplane of the base board 130 may drive the light emitting element package 110, the light emitting assembly 100 shown in FIG. 11 may use the integrated circuit 175 to drive the light emitting element package 110 instead. Including an integrated circuit 175 with the light emitting element package 110 may allow the light emitting element package 110 to be installed on electrical bus lines printed directly on or into the first glass layer 151. Thus, a structure of the light emitting assembly 100 may be simplified. Additionally, manufacturing of the light emitting assembly 100 may be simplified.

FIG. 12 shows a schematic cross-sectional view of a light emitting assembly 100 according to one or more embodiments. While the light emitting assembly 100 shown in FIG. 12 is configured to be part of a second light emitting structure 41 of a rear window 40 (see FIGS. 2 and 4), such a structure may be disposed on a first light emitting structure 31 of a front windshield 30 (see FIGS. 1 and 3) by rotating (i.e., flipping) the light emitting assembly 100. As noted above, the front windshield 30 and/or the rear window 40 may include curved portions. Therefore, as shown in FIG. 12, if the base board 130 is disposed at the curved portions, inclines of the base board 130 with respect to the longitudinal axis AxL may differ at positions of the base board 130 in which the light emitting element packages 110 and the reflectors 121 are disposed. According to one or more embodiments, the light emitting assembly 100 may include differently shaped reflectors 121 such that an acute angle α formed between a reflection surface 123 of the reflector 121 and the mounting surface 131 of the base board 130 may differ for the different reflectors 121. According to one or more embodiments, the reflectors 121 may be structured to such that the acute angles α at each location satisfies the equation α=90°−θr/2 if disposed on a rear window 40 (see FIGS. 2, 4, and 7) or the equation α=90°−θf/2 if disposed on a front windshield 30 (see FIGS. 1 and 3).

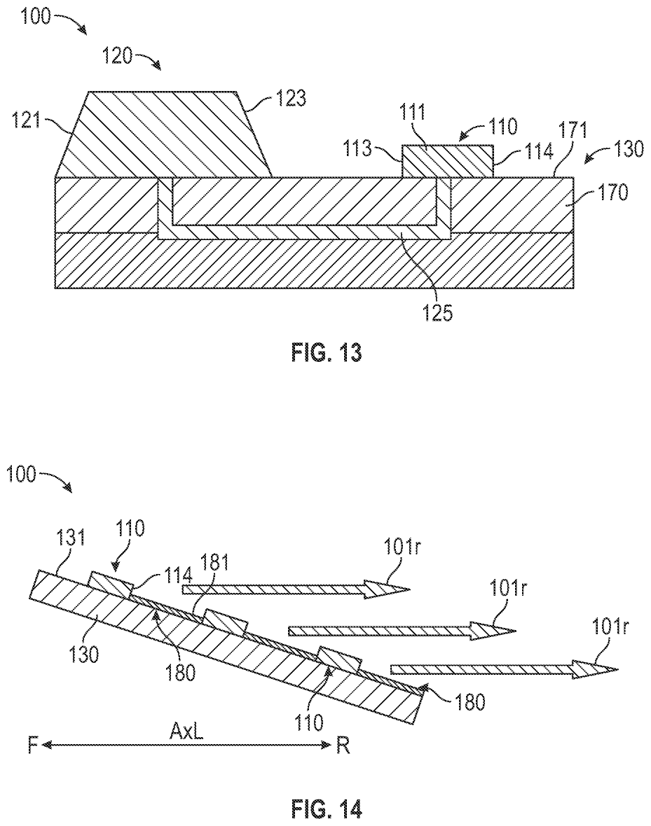

FIG. 13 shows a schematic cross-sectional view of a light emitting assembly 100 according to one or more embodiments. The base board 130 may include an insulation layer 170 under the light emitting element package 110 and the reflector 121 of the electrode 120. The connector 125 may be embedded within the insulation layer 170 and extend between the light emitting element package 110 and the electrode 120.

FIG. 14 shows a schematic cross-sectional view of a light emitting assembly 100 according to one or more embodiments. While the light emitting assembly 100 shown in FIG. 14 is configured to be part of a second light emitting structure 41 of a rear window 40 (see FIGS. 2 and 4), such a structure may be disposed on a first light emitting structure 31 of a front windshield 30 (see FIGS. 1 and 3) by rotating (i.e. flipping) the light emitting assembly 100. The light emitting assembly 100 may include a base board 130 having light emitting element packages 110 and reflective layers 180 disposed on a mounting surface 131 thereof. The light emitting element packages 110 have a light emitting surface 114 that is configured to emit light towards a reflective surface 181 of the reflective layer 180. The reflective surface 181 is structured to reflect light emitted from the light emitting surface 114 in a rearward direction R of the vehicle 10 as rearward light 101r.

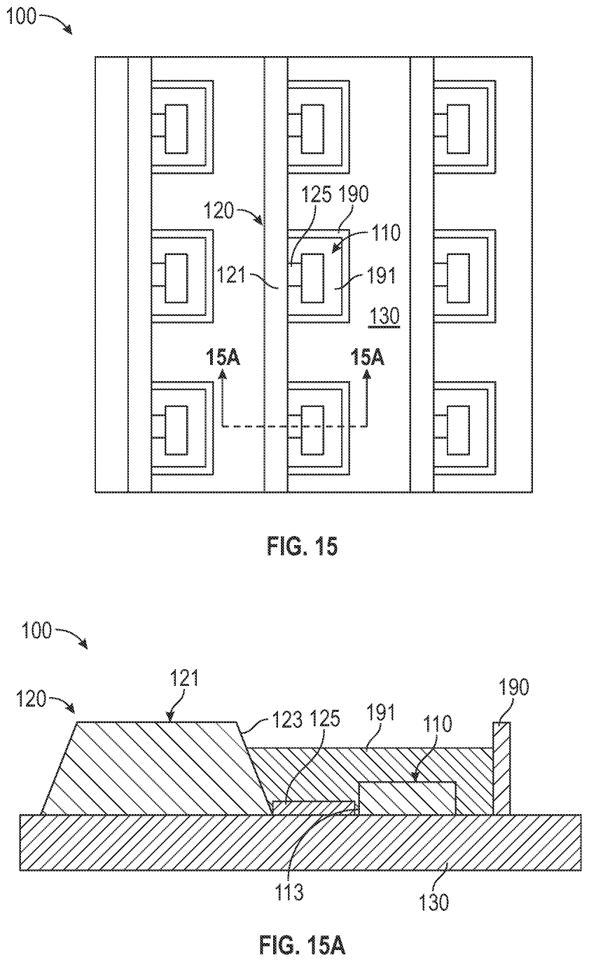

FIG. 15 shows a schematic orthogonal view of a light emitting assembly 100 according to one or more embodiments, and FIG. 15A shows a schematic cross-sectional view of the light emitting assembly 100 taken at 15A-15A. The light emitting assembly 100 shown in FIGS. 15 and 15A are similar to that shown in FIGS. 5-6, but further includes a color conversion material 191 on the base board 130 covering the light emitting element package 110. The color conversion material 191 may also cover at least a portion of the reflection surface 123 of the reflector 121. The color conversion material 191 may convert a color of light from the light emitting element package 110. A stiffening structure 190 may surround at least a portion of the color conversion material 191. The stiffening element 190 may provide stiffness to the light emitting element package 110 and/or the color conversion material 191 to reduce or prevent deformation.

A light emitting assembly 100 according to one or more embodiments may be integrated into a front windshield 30 or a rear window 40 and may eliminate the need for some lighting systems to be disposed in a vehicle body 12 of the vehicle 10.

A light emitting assembly 100 according to one or more embodiments includes reflectors 121 disposed on electrodes 120. The reflectors 121 may redirect light from the light emitting element packages 110 in a desired direction so as to improve a lighting efficiency of the light emitting assembly 100, while the reflectors 121 being disposed on the electrodes 120 may avoid or minimize additional space of the light emitting assembly 100 being taken up by the reflectors 121. Furthermore, by increasing lighting efficiency of the light emitting assembly 100, less power is required for the light emitting element packages 110 such that a width of the electrode 120 may be reduced to achieve a similar brightness in a desired illumination area.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A light emitting assembly configured to be disposed within a vehicle window of a vehicle, comprising:
a light emitting element package configured to emit light from a light emitting surface; and
a reflector having a reflection surface that faces the light emitting surface and that is configured to reflect light from the light emitting element package.

2. The light emitting assembly of claim 1,
wherein the vehicle defines a longitudinal axis,
wherein the light emitting assembly forms a first angle θ with the longitudinal axis, and
wherein the reflection surface is configured to reflect at least some light from the light emitting element package in a direction along the longitudinal axis.

3. The light emitting assembly of claim 2, further comprising:
a base board on which the reflector is disposed,
wherein the reflection surface forms a second angle α with the base board, and
wherein the reflector is structured such that the second angle α satisfies an equation α=90°−θ/2.

4. The light emitting assembly of claim 1, further comprising:
an electrode electrically connected to the light emitting element package and configured to supply power to the light emitting element package,
wherein the reflector is disposed on the electrode.

5. The light emitting assembly of claim 1, further comprising:
a first electrode extending in a first direction, and
a second electrode extending in a second direction different from the first direction,
wherein the reflector is disposed on the first electrode or the second electrode.

6. The light emitting assembly of claim 1, further comprising a collimator disposed between the light emitting element package and the reflection surface of the reflector configured to converge light emitted by the light emitting element package towards the reflection surface.

7. The light emitting assembly of claim 1, wherein the light emitting element package is disposed on an integrated circuit.

8. The light emitting assembly of claim 1, further comprising:
an electrode on which the reflector is disposed,
an insulation layer on which the light emitting element package and the electrode are disposed, and
a connector disposed in the insulation layer connecting the light emitting element package and the electrode.

9. The light emitting assembly of claim 1, further comprising:
a base board having a mounting surface on which the light emitting element package is disposed,
wherein the reflector is a reflective layer disposed on a mounting surface of the base board.

10. A vehicle window of a vehicle, comprising:
a light emitting assembly, comprising:
a light emitting element package configured to emit light from a light emitting surface; and
a reflector having a reflection surface that faces the light emitting surface and that is configured to reflect light from the light emitting element package.

11. The vehicle window of claim 10,
wherein the vehicle defines a longitudinal axis,
wherein the light emitting assembly forms a first angle θ with the longitudinal axis, and
wherein the reflection surface is configured to reflect at least some light from the light emitting element package in a direction along the longitudinal axis.

12. The vehicle window of claim 11, further comprising:
a base board on which the reflector is disposed,
wherein the reflection surface forms a second angle α with the base board, and
wherein the reflector is structured such that the second angle α satisfies an equation α=90°−θ/2.

13. The vehicle window of claim 10, further comprising:
an electrode electrically connected to the light emitting element package and configured to supply power to the light emitting element package,
wherein the reflector is disposed on the electrode.

14. The vehicle window of claim 10, further comprising:
a first electrode extending in a first direction,
a second electrode extending in a second direction different from the first direction, and
wherein the reflector is disposed on the first electrode or the second electrode.

15. The vehicle window of claim 10, further comprising a collimator disposed between the light emitting element package and the reflection surface of the reflector configured to converge light emitted by the light emitting element package towards the reflection surface.

16. The vehicle window of claim 10, wherein the light emitting element package is disposed on an integrated circuit.

17. The vehicle window of claim 10, further comprising:
an electrode on which the reflector is disposed,
an insulation layer on which the light emitting element package and the electrode are disposed, and
a connector disposed in the insulation layer connecting the light emitting element package and the electrode.

18. The vehicle window of claim 10, further comprising:
a base board having a mounting surface on which the light emitting element package is disposed,
wherein the reflector is a reflective layer disposed on a mounting surface of the base board.

19. The vehicle window of claim 10, wherein the light emitting element package and the reflector are disposed between a first glass layer and a second glass layer.

20. A vehicle defining a longitudinal axis and a forward direction and a rear direction along the longitudinal axis, comprising:
a vehicle window comprising a light emitting assembly, the light emitting assembly comprising:
a light emitting element package configured to emit light from a light emitting surface;
an electrode electrically connected to the light emitting element package and configured to supply power to the light emitting element package;
a reflector disposed on the electrode and having a reflection surface that faces the light emitting surface and that is configured to reflect light from the light emitting element package; and
a base board on which the reflector is disposed,
wherein the light emitting assembly forms a first angle θ with the longitudinal axis,
wherein the reflection surface is configured to reflect at least some light from the light emitting element package in a direction along the longitudinal axis,
wherein the reflection surface forms a second angle α with the base board, and
wherein the reflector is structured such that the second angle α satisfies an equation α=90°−θ/2.
